(19) United States
(12) Patent Application Publication
(10) Pub. No.: US 2013/0126214 A1
(43) Pub. Date: May 23, 2013

(54) FIXING APPARATUS FOR HEAT SINK

(71) Applicants: MENG-HSIEN LIN, Tu-Cheng (TW); YAO-TING CHANG, Tu-Cheng (TW)

(72) Inventors: MENG-HSIEN LIN, Tu-Cheng (TW); YAO-TING CHANG, Tu-Cheng (TW)

(73) Assignee: HON HAI PRECISION INDUSTRY CO., LTD., Tu-Cheng (TW)

(21) Appl. No.: 13/337,062

(22) Filed: Dec. 24, 2011

(30) Foreign Application Priority Data
Nov. 23, 2011 (TW) 100142838

(51) Int. Cl. H05K 1/00

(52) U.S. Cl. 174/250

(57) ABSTRACT

An apparatus for fixing a heat sink having a bottom plate includes a circuit board, two fasteners, and two blocks. The circuit board defines two through holes. The fasteners respectively extend through the bottom plate of the heat sink for fixing the heat sink to the circuit board. Each of the fasteners includes two spaced feet to extend through a corresponding one of the through holes and engage with a bottom of the circuit board. Each of the blocks is inserted into a space between the feet of a corresponding one of the fasteners after the feet extend through the corresponding through hole, to prevent the feet from deforming and disengaging from the circuit board.

### BACKGROUND

1. Technical Field

The present disclosure relates to an apparatus for fixing a heat sink.

2. Description of Related Art

A heat sink is generally mounted to a circuit board by a plurality of fasteners each having two feet. However, the feet of the fasteners are apt to be deformed, which may cause the heat sink to be loosened or disengaged from the circuit board.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an exemplary embodiment of a fixing apparatus together with a heat sink.

FIG. 2 is an inverted view of FIG. 1.

FIG. 3 is an assembled, isometric view of FIG. 1.

FIG. 4 is an assembled, isometric view of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

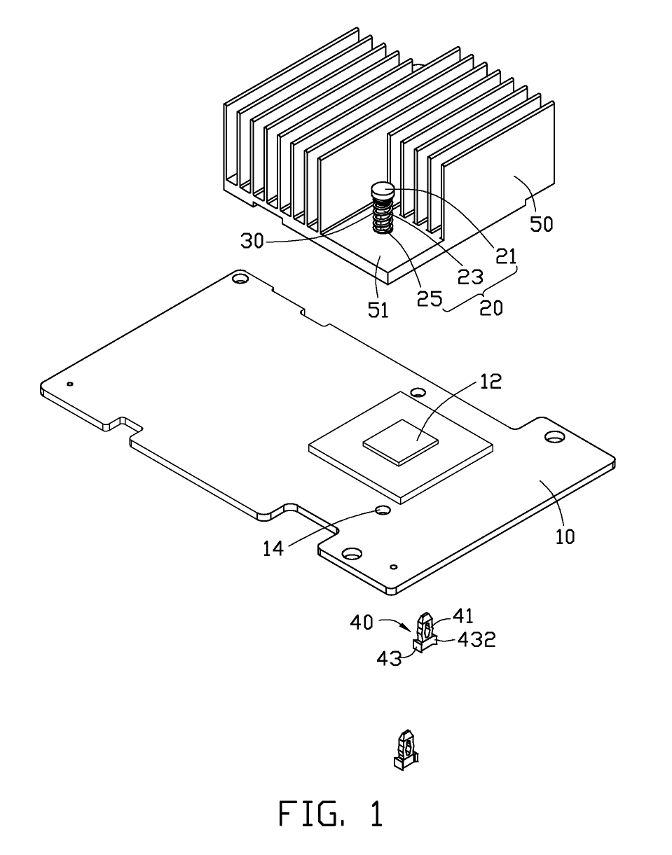

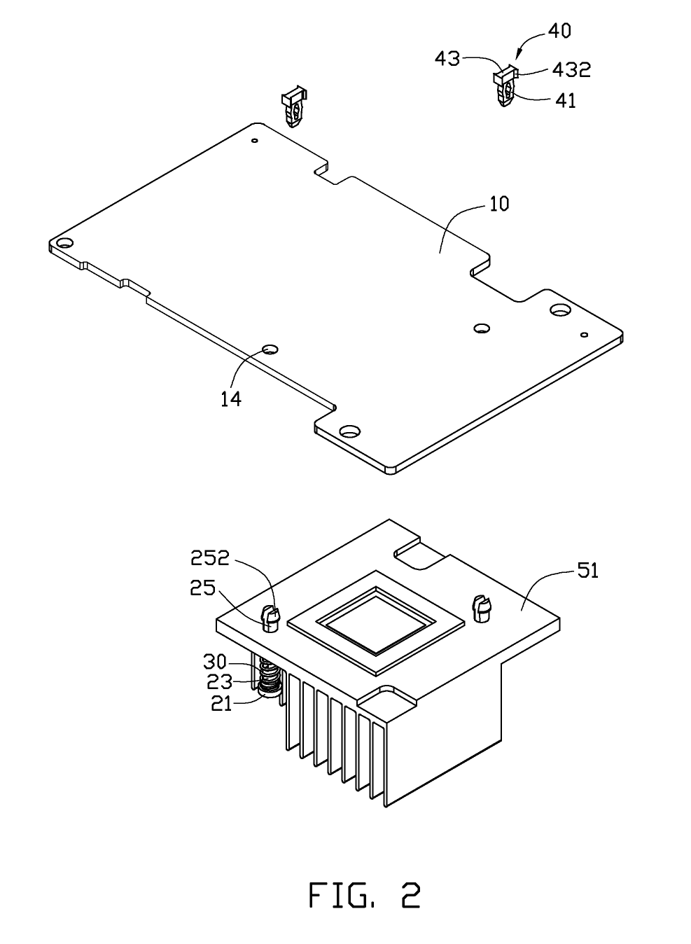

FIGS. 1 and 2, an exemplary embodiment of a fixing apparatus is provided to fix a heat sink 50 having a bottom plate 51. Two through holes (not shown) are respectively defined in opposite corners of the bottom plate 51. The fixing apparatus includes a circuit board 10, two metal fasteners 20, two springs 30, and two plastic blocks 40.

An electronic element 12 is mounted on the circuit board 10. Two through holes 14 are defined in the circuit board 10 respectively adjacent to opposite corners of the electronic element 12.

Each fastener 20 includes a head 21, a pole 23 perpendicularly extending from a side surface of the head 21, and two spaced feet 25 extending from a distal end of the pole 23 away from the head 21. A latching portion 252 protrudes from a distal end of each foot 25, away from the opposite foot 25.

Each block 40 includes a main body 41, and two protrusions 43 extending outwards from opposite ends of the bottom of the main body 41. Two flanges 432 extend outwards from opposite sides of each protrusion 43.

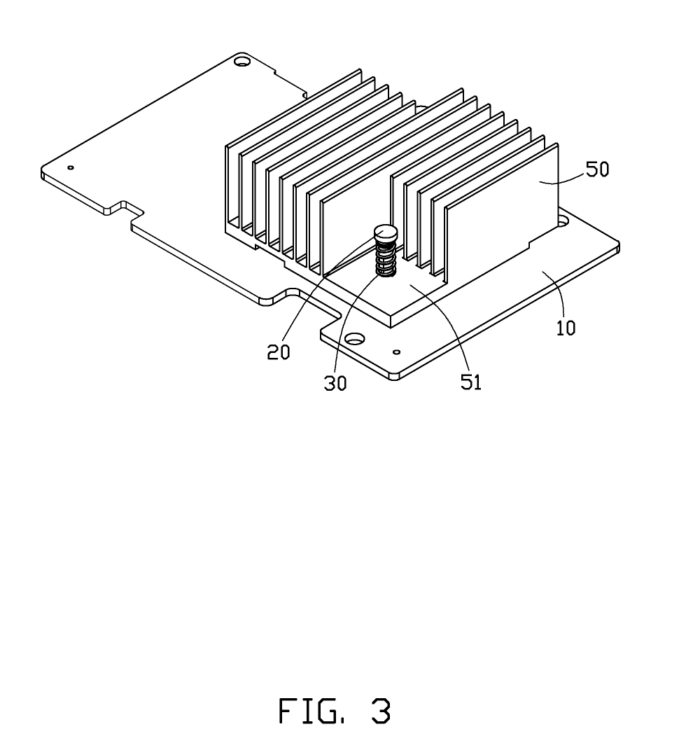

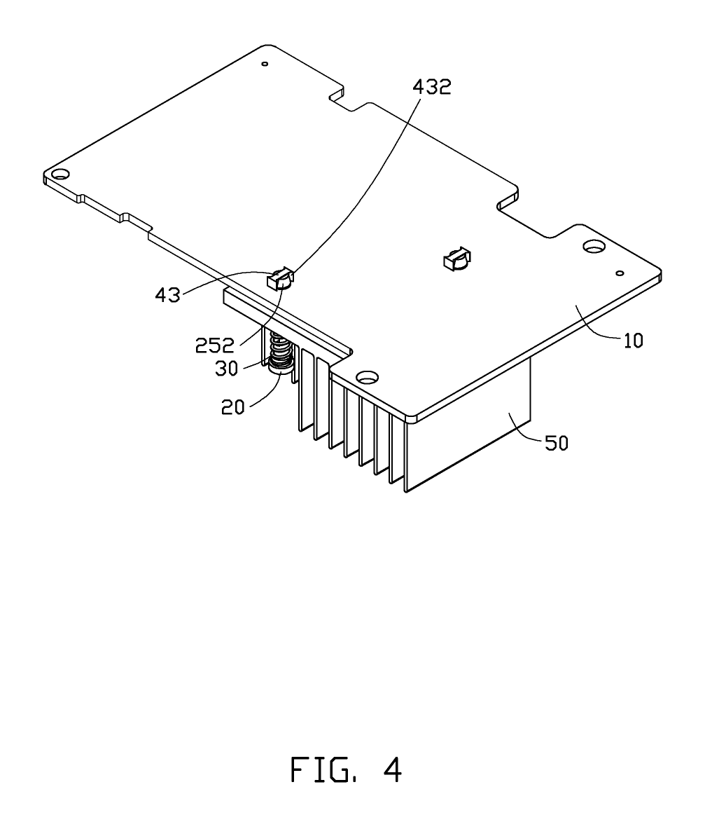

FIGS. 3 and 4, in assembly, the bottom plate 51 is placed on the top of the electronic element 12, to allow the through holes of the bottom plate 51 to respectively align with the through holes 14. The feet 25 of each fastener 20 are deformed toward each other to extend through a corresponding spring 30, a through hole of the bottom plate 51, and a corresponding through hole 14. The feet 25 are then self-restored to allow the latching portions 252 to engage with the bottom of the circuit board 10. Thereby, the heat sink 50 is fixed to the circuit board 10. Each spring 30 is placed around a corresponding pole 23 and sandwiched between the bottom plate 51 and a corresponding head 21 to tightly press the heat sink 50 to the circuit board 10. A block 40 is inserted into a space between the feet 25 of each fastener 20, to allow the main body 41 to be sandwiched between the feet 25. The blocks 40 also allow each latching portion 252 to be sandwiched between two corresponding flanges 432 at one side of the main body 41. Thereby, the blocks 40 are respectively fixed to the fasteners 20. The blocks 40 can prevent the feet 25 from deforming, and further prevent the feet 25 from disengaging from the corresponding through holes 14.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A fixing apparatus for fixing a heat sink having a bottom plate, the fixing apparatus comprising:
a circuit board defining two through holes;
two fasteners for fixing the heat sink to the circuit board by extending through the bottom plate of the heat sink, each of the fasteners comprising two spaced feet to extend through a corresponding one of the through holes and engage with a bottom of the circuit board; and
two blocks, wherein each of the blocks is inserted into a space between the feet of a corresponding one of the fasteners after the feet extend through the corresponding through hole, to prevent the feet from deforming and disengaging from the circuit board.

2. The fixing apparatus of claim 1, further comprising two springs, wherein each of the fasteners further comprises a head and a pole extending from the head, the feet extends from a distal end of the pole away from the head, each spring is placed around a corresponding one of the poles and sandwiched between the bottom plate and a corresponding head.

3. The fixing apparatus of claim 1, wherein each of the feet comprises a latching portion at a distal end facing away from the opposite one of the feet, to engage with the bottom of the circuit board.

4. The fixing apparatus of claim 3, wherein each of the fasteners is made of metal.

5. The fixing apparatus of claim 3, wherein each of the blocks comprises a main body to be sandwiched between the feet of a corresponding fastener, and two protrusions extending outwards from opposite ends of a bottom of the main body, two flanges extend outwards from opposite sides of each protrusion, each latching portion of the fastener is sandwiched between two corresponding flanges at one side of the main body after the main body is inserted into the fastener.

6. The fixing apparatus of claim 5, wherein each of the blocks is made of a plastic material.
